(19) United States
(12) Patent Application Publication
(10) Pub. No.: US 2026/0336647 A1
(43) Pub. Date: Oct. 29, 2026

(54) DIGITAL TWIN FOR A FUEL SYSTEM

(71) Applicant: Cummins Inc., Columbus, IN (US)

(72) Inventors: Mayur H. Borate, Pune (IN); Shailesh Nair, Pune (IN); Srinivas Kumar Mulukutla, Pune (IN); David Michael Carey, Bend, OR (US); Pradheepram Ottikkutti, Erie, PA (US)

(73) Assignee: Cummins Inc., Columbus, IN (US)

(21) Appl. No.: 19/103,819

(22) PCT Filed: Sep. 15, 2023
(86) PCT No.: PCT/US2023/032888

§ 371 Date: Feb. 13, 2025

(30) Foreign Application Priority Data
Sep. 17, 2022 (IN) 202241053236

(51) Int. Cl. B60W 50/14; B60W 50/00; B60W 50/02

(52) U.S. Cl. CPC B60W 50/14; B60W 50/0205; B60W 2050/0031; B60W 2050/021; B60W 2050/146; B60W 2510/0614; B60W 2556/45

(57) ABSTRACT

Systems and apparatuses include one or more processing circuits having one or more memory devices coupled to one or more processors. The one or more memory devices are configured to store instructions thereon that, when executed by the one or more processors, cause the one or more processors to: receive information from at least one sensor; control operation of a vehicle subsystem based on the information; generate a digital twin output based on the information; generate a prioritized list of faults based on the digital twin output; and, provide the prioritized list to a dashboard.

### CROSS-REFERENCE TO RELATED APPLICATION

The present application claims the benefit of and priority to Indian Provisional Patent Application No. 202241053236, titled “Digital Twin for a Fuel System,” filed Sep. 17, 2022, which is incorporated herein by reference in its entirety and for all purposes.

### TECHNICAL FIELD

The present disclosure relates to fault detection in vehicle systems. More particularly, the present disclosure relates to systems and methods for determining faults and root causes for a vehicle system or subsystem using a digital twin.

### BACKGROUND

Many vehicles include fueling systems. Fueling systems include various components, such as pumps, injectors, and sensors. The fueling system is often a complex vehicle system. Given the complexity and when issues arise, diagnosing the fueling system can be resource intensive and time consuming. Improved systems and methods for diagnosing vehicle systems, such as fueling systems, is desired.

### SUMMARY

One embodiment relates to an apparatus that includes one or more processing circuits comprising one or more memory devices coupled to one or more processors. The one or more memory devices are configured to store instructions thereon that, when executed by the one or more processors, cause the one or more processors to: receive information from at least one sensor; control operation of a vehicle subsystem based on the information; generate a digital twin output based on the information; generate a prioritized list of faults based on the digital twin output; and provide the prioritized list to a dashboard.

In some embodiments, the one or more processing circuits are located on-board a vehicle and, in particular, reside within an engine control module. In some embodiments, the digital twin output includes a fueling on-time-to-quantity indicator regarding a fuel injector. The one or more memory devices may be further configured to store instructions thereon that, when executed by the one or more processors, cause the one or more processors to: compare the digital twin output to an actual output; and generate the prioritized list of faults based on a correlation of the digital twin output to the actual output. In some embodiments, the one or more memory devices may be further configured to store instructions thereon that, when executed by the one or more processors, cause the one or more processors to determine a plurality of faults based on prompts above a threshold correlation. In some embodiments, the one or more memory devices may be further configured to store instructions thereon that, when executed by the one or more processors, cause the one or more processors to interface with a second digital twin on a remote control system.

Another embodiment relates to a system. The system may include a vehicle system and a controller coupled to the vehicle system. The controller may have one or more processors coupled with at least one memory. The controller may be configured to: receive information from at least one sensor; control operation of the vehicle system based on the information; generate a digital twin output based on the information; generate a prioritized list of faults based on the digital twin output; and provide the prioritized list to a user interface on a computing device. In some embodiments, the controller may be configured to compare the digital twin output to an output of the vehicle subsystem to determine a correlation. In some embodiments, the controller may be configured to generate the prioritized list of faults based on the correlation of the digital twin output to the output. In some embodiments, the controller may be configured to determine a plurality of faults based on prompts above a threshold correlation. In some embodiments, the controller may be configured to communicate with a second digital twin on a remote control system to send telematics data.

In some embodiments, the controller may determine, using an artificial intelligence model of the digital twin, the digital twin output from the information. In some embodiments, the digital twin output may include a fueling on-time-to-quantity indicator regarding a fuel injector. In some embodiments, the controller may reside on a vehicle. In some embodiments, the vehicle system comprises at least one of an aftertreatment system, a transmission, or an engine.

Yet another embodiment relates to a method of generating a prioritized list of faults using a digital twin. The method includes: receiving, by one or more processors, information from at least one sensor; controlling, by the one or more processors, operation of a vehicle system based on the information; generating, by the one or more processors, a digital twin output based on the information; generating, by the one or more processors, a prioritized list of faults based on the digital twin output; and providing, by the one or more processors, the prioritized list to an interface on a computing device. In some embodiments, the method includes: comparing, by the one or more processors, the digital twin output to an output of the vehicle system to determine a correlation; and generating, by the one or more processors, the prioritized list of faults based on the correlation of the digital twin output to the output. In some embodiments, the method includes determining, by the one or more processors, a plurality of faults based on prompts above a threshold correlation. In some embodiments, the method includes communicating, by the one or more processors, with a second digital twin on a remote control system. In some embodiments, the method includes determining, by the one or more processors and using an artificial intelligence model of the digital twin, the digital twin output from the information. In some embodiments, the one or more processors may be at least part of a controller residing on a vehicle.

This summary is illustrative only and is not intended to be in any way limiting. Other aspects, inventive features, and advantages of the devices or processes described herein will become apparent in the detailed description set forth herein, taken in conjunction with the accompanying figures, wherein like reference numerals refer to like elements.

Numerous specific details are provided to impart a thorough understanding of embodiments of the subject matter of the present disclosure. The described features of the subject matter of the present disclosure may be combined in any suitable manner in one or more embodiments and/or implementations. In this regard, one or more features of an aspect of the invention may be combined with one or more features of a different aspect of the invention. Moreover, additional features may be recognized in certain embodiments and/or implementations that may not be present in all embodiments or implementations.

### BRIEF DESCRIPTION OF THE FIGURES

FIG. 1 is a schematic diagram of a vehicle, according to some embodiments.

FIG. 2 is a schematic diagram of a controller of the vehicle of FIG. 1, according to some embodiments.

FIG. 3 is a schematic diagram of a control architecture of the controller of FIG. 2, according to some embodiments.

FIG. 4 is a graph representing a default curve and an adapted curve generated by the control architecture of FIG. 3, according to some embodiments.

FIG. 5 is a graph representing a default curve and an adapted curve generated by the control architecture of FIG. 3, according to some embodiments.

FIG. 6 is a graph representing a default curve and an adapted curve generated by the control architecture of FIG. 3, according to some embodiments.

FIG. 7 is a graph representing a default curve and an adapted curve generated by the control architecture of FIG. 3, according to some embodiments.

FIG. 8 is a flow diagram of a method of generating a prioritized list of root causes using a digital twin of the controller of FIG. 2, according to some embodiments.3

FIG. 9 is an exemplary schematic representation of the method of FIG. 8, according to some embodiments.

### DETAILED DESCRIPTION

Following below are more detailed descriptions of various concepts related to, and implementations of, methods, apparatuses, and systems for utilizing a digital twin to determine faults and root causes for a vehicle system. Before turning to the figures, which illustrate certain exemplary embodiments in detail, it should be understood that the present disclosure is not limited to the details or methodology set forth in the description or illustrated in the figures. It should also be understood that the terminology used herein is for the purpose of description only and should not be regarded as limiting.

Referring to the figures generally, the various embodiments disclosed herein relate to systems, apparatuses, and methods for a digital twin of a vehicle system of subsystem (e.g., a fuel injector) that is used to identify faults, and generate a prioritized list of root causes related to the identified fault. The digital twin receives the same inputs as a vehicle controller (e.g., an engine control unit) and includes a control architecture that can introduce errors into a digital twin model. The digital twin can then generate an expected outcome in response to the introduced error. The expected outcome is then compared to the real world outcome of the system and the comparison can be used to assign priority of the introduced errors. For example, the better the expected outcome matches the real world outcome, the higher priority assigned. In some embodiments, the real world outcome includes more than one expected outcome and the digital twin can rank or prioritize each expected outcome. The systems, methods, and apparatuses described herein may then enable improved diagnostic and prognostic capabilities as compared to conventional systems.

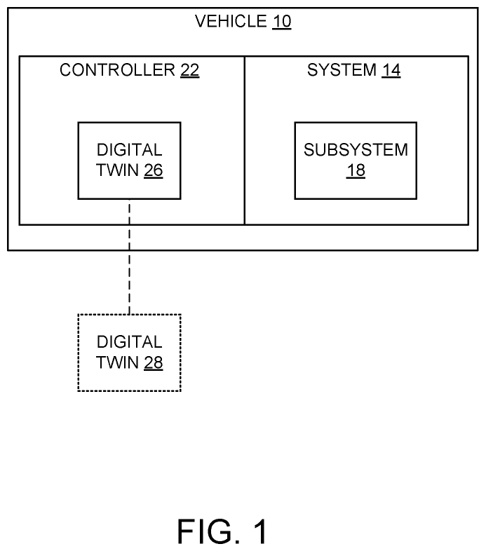

As shown in FIG. 1, a vehicle 10 includes a system 14 in the form of an engine and a subsystem 18 in the form of a fuel injector. In some embodiments, the system 14 includes an aftertreatment system, a transmission, or another vehicle system. In some embodiments, the subsystem 18 includes a different component (e.g., a diesel exhaust fluid dosing pump, an oxygen sensor, a transmission shift actuator, etc.). The system 14 and subsystem 18 can includes any component or system of the vehicle 10 that is monitored for faults, aging, or may otherwise require maintenance or replacement. While portions of the description that follows are directed to a fuel injector for an engine, other systems and subsystems can utilize the concepts, apparatuses, systems, and methods described herein.

The vehicle 10 also includes a controller 22 in the form of an engine control unit. In some embodiments, the controller 22 is a transmission control unit, a dedicated (i.e., separate) controller, or another controller of the vehicle 10. The controller 22 controls operation of the system 14 and/or the subsystem 18. For example, the controller 22 controls a fuel pump and fuel injector during operation of the vehicle 10.

The controller 22 includes a digital twin 26 that includes a policy that mimics the operation of the system 14 and the subsystem 18. The digital twin 26 resides on the controller 22 locally and receives the same inputs (e.g., sensors, actuator feedback, external information etc.) as the controller 22. The digital twin 26 provides a digital copy of the operational states and output information of the system 14 and the subsystem 18.

In some embodiments, a remote digital twin 28 is maintained in parallel with the digital twin 26. In some embodiments, the remote digital twin 28 is provided on a cloud or network based server, a dedicated remote server, a computer or other processor remote from the vehicle 10, or any combination of locations. The remote digital twin 28 may operate similar to the digital twin 26 to provide a remote representation of the system 14 and/or subsystem 18. While the following description references the actions of the digital twin 26, the same actions can also exist in the remote digital twin 28.

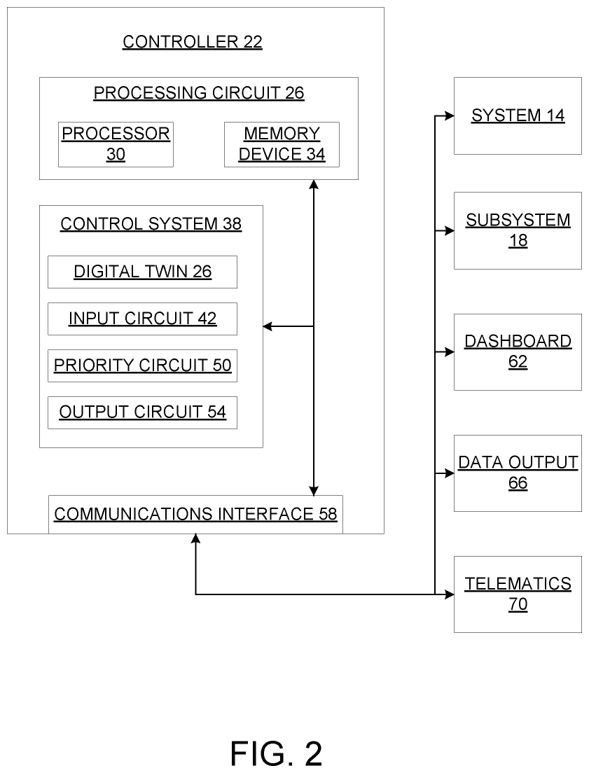

As the components of FIG. 1 are shown to be embodied in the vehicle 10, the controller 22 may be structured as one or more electronic control units (ECU) (e.g., an engine control module (ECM)). The controller 22 may be separate from or included with at least one of a transmission control unit, an exhaust aftertreatment control unit, a powertrain control module, an engine control module, etc. The function and structure of the controller 22 is described in greater detail in FIG. 2.

Referring now to FIG. 2, a schematic diagram of the controller 22 of the vehicle 10 of FIG. 1 is shown according to an example embodiment. As shown in FIG. 2, the controller 22 includes a processing circuit 26 having a processor 30 and a memory device 34, a control system 38 having the digital twin 26, an input circuit 42, a priority circuit 50, and an output circuit 54. The controller 22 also includes a communications interface 58. Generally, the controller 22 is structured to operate the system 14 and the subsystem 18, and to operate the digital twin 26 to identify faults and prioritize potential root causes to address the identified faults.

In one configuration, the control system 38 is embodied as machine or computer-readable media that is executable by a processor, such as processor 30. As described herein and amongst other uses, the machine-readable media facilitates performance of certain operations to enable reception and transmission of data. For example, the machine-readable media may provide an instruction (e.g., command, etc.) to, e.g., acquire data. In this regard, the machine-readable media may include programmable logic that defines the frequency of acquisition of the data (or, transmission of the data). The computer readable media may include code, which may be written in any programming language including, but not limited to, Java or the like and any conventional procedural programming languages, such as the “C” programming language or similar programming languages. The computer readable program code may be executed on one processor or multiple remote processors. In the latter scenario, the remote processors may be connected to each other through any type of network (e.g., CAN bus, etc.).

In another configuration, the control system 38 is embodied as hardware units, such as electronic control units. As such, the control system 38 may be embodied as one or more circuitry components including, but not limited to, processing circuitry, network interfaces, peripheral devices, input devices, output devices, sensors, etc. In some embodiments, the control system 38 may take the form of one or more analog circuits, electronic circuits (e.g., integrated circuits (IC), discrete circuits, system on a chip (SOCs) circuits, microcontrollers, etc.), telecommunication circuits, hybrid circuits, and any other type of “circuit.” In this regard, the control system 38 may include any type of component for accomplishing or facilitating achievement of the operations described herein. For example, a circuit as described herein may include one or more transistors, logic gates (e.g., NAND, AND, NOR, OR, XOR, NOT, XNOR, etc.), resistors, multiplexers, registers, capacitors, inductors, diodes, wiring, and so on). The control system 38 may also include programmable hardware devices such as field programmable gate arrays, programmable array logic, programmable logic devices or the like. The control system 38 may include one or more memory devices for storing instructions that are executable by the processor(s) of the control system 38. The one or more memory devices and processor(s) may have the same definition as provided below with respect to the memory device 34 and processor 30. In some hardware unit configurations, the control system 38 may be geographically dispersed throughout separate locations in the vehicle. Alternatively and as shown, the control system 38 may be embodied in or within a single unit/housing, which is shown as the controller 22.

In the example shown, the controller 22 includes the processing circuit 26 having the processor 30 and the memory device 34. The processing circuit 26 may be structured or configured to execute or implement the instructions, commands, and/or control processes described herein with respect to control system 38. The depicted configuration represents the control system 38 as machine or computer-readable media. However, as mentioned above, this illustration is not meant to be limiting as the present disclosure contemplates other embodiments where the control system 38, or at least one circuit of the control system 38, is configured as a hardware unit. All such combinations and variations are intended to fall within the scope of the present disclosure.

The hardware and data processing components used to implement the various processes, operations, illustrative logics, logical blocks, modules and circuits described in connection with the embodiments disclosed herein (e.g., the processor 30) may be implemented or performed with a general purpose single-or multi-chip processor, a digital signal processor (DSP), an application specific integrated circuit (ASIC), a field programmable gate array (FPGA), or other programmable logic device, discrete gate or transistor logic, discrete hardware components, or any combination thereof designed to perform the functions described herein. A general purpose processor may be a microprocessor, or, any conventional processor, or state machine. A processor also may be implemented as a combination of computing devices, such as a combination of a DSP and a microprocessor, a plurality of microprocessors, one or more microprocessors in conjunction with a DSP core, or any other such configuration. In some embodiments, the one or more processors may be shared by multiple circuits (e.g., control system 38 may comprise or otherwise share the same processor which, in some example embodiments, may execute instructions stored, or otherwise accessed, via different areas of memory). Alternatively or additionally, the one or more processors may be structured to perform or otherwise execute certain operations independent of one or more co-processors. In other example embodiments, two or more processors may be coupled via a bus to enable independent, parallel, pipelined, or multi-threaded instruction execution. All such variations are intended to fall within the scope of the present disclosure.

The memory device 34 (e.g., memory, memory unit, storage device) may include one or more devices (e.g., RAM, ROM, Flash memory, hard disk storage) for storing data and/or computer code for completing or facilitating the various processes, layers and modules described in the present disclosure. The memory device 34 may be communicably connected to the processor 30 to provide computer code or instructions to the processor 30 for executing at least some of the processes described herein. Moreover, the memory device 34 may be or include tangible, non-transient volatile memory or non-volatile memory. Accordingly, the memory device 34 may include database components, object code components, script components, or any other type of information structure for supporting the various activities and information structures described herein.

The input circuit 42 is structured to receive and process information received from sensors and actuators of the system 14 and the subsystem 18. For example, the input circuit 42 can receive pressure information from a fuel rail pressure sensor, temperature information from a fuel rail temperature sensor, flow rate information from an injector flow rate sensor, injector on time information from a transistor-transistor logic (TTL) system, pump status information from a fuel pump, fuel quality information from a fuel quality sensor, and other inputs as desired. The input circuit 42 is structured to process the received information for use within the control system 38. In some embodiments, the inputs received by the input circuit 42 are different and related to a different system 14 and/or subsystem 18. For example, if the digital twin 26 is replicating an oxygen sensor, the input circuit 42 can receive information indicative of operation of the oxygen sensor (e.g., upstream NOx, downstream NOx, engine out temperature, system out temperature, flow rate information, etc.).

The digital twin 26 is structured to receive the information processed by the input circuit 42. The controller 22 is structured to control operation of the system 14 and/or subsystem 18 using the information processed by the input circuit 42 in parallel with the operation of the digital twin 26. In some embodiments, the digital twin 26 is located locally on the controller 22 within the vehicle 10. The digital twin 26 is structured to implement a policy to replicate the status and outputs of the system 14 and/or subsystem. The output of the digital twin 26 provides an expected outcome based on the processed information and digital twin prompts determined by the policy. For example, when the subsystem 18 is the fuel injector, the output of the digital twin 26 is a fueling on-time: quantity curve at a given rail pressure. The prompts determined by the policy may include potential error sources that the digital twin 26 would like to test for (e.g., a descending list of likely faults or failures).

In some embodiments, the policy includes an artificial intelligence engine that learns over time to accurately replicate the system 14 and/or subsystem 18. The artificial intelligence engine may be of any architecture, such as an artificial neural network (ANN), a support vector machine (SVM), a clustering algorithm (e.g., k-means clustering), a Naïve Bayesian classifier, a regression model (e.g., linear or logistic regression), and factor analysis, among others, or any combination thereof. The artificial intelligence engine may be trained using training data in accordance with learning techniques (e.g., supervised or unsupervised). The training data may include inputs (e.g., prompts or sensor data from the system 14 or subsystem 18) and expected outputs for the associated inputs. Once trained, the artificial intelligence engine on the digital twin 26 may be used to process new inputs (e.g., prompts or sensor data) to generate new expected output. In some embodiments, the policy is model based (e.g., a set of equations) and can be updated periodically (e.g., on a set time schedule, at each service event for the vehicle 10, at a predetermined mileage interval, etc.). During operation of the digital twin 26, the policy will inject prompts and output associated expected outcomes. In this way, the digital twin 26 generates a list of expected outcomes and associated prompts (i.e., error inputs).

The priority circuit 50 is structured to receive the expected outcomes and associated prompts from the digital twin 26, and processed information from the input circuit 42. The priority circuit 50 compares the expected outcomes to the real world or default outcomes of the system 14 and/or subsystem 18. For example, the priority circuit 50 compares the fueling on-time: quantity curve of the fuel injector provided by the digital twin 26 to a default or real-world fueling on-time: quantity curve. The strength of a correlation between the digital twin output and the real world output is used to define a priority of the digital twin output. For example, a highly correlated digital twin output (i.e., a good match) will be assigned a higher priority than a low correlation digital twin output (i.e., a bad match). The priority circuit 50 generates a descending fault list of digital twin outputs ordered from highest to lowest priority.

The output circuit 54 is structured to receive the fault list from the priority circuit 50 and to associate a set of top digital twin outputs with root causes for each of the top digital twin outputs. In some embodiments, the top digital twin outputs are defined with priority above a threshold value. For example, the top digital twin outputs may include any digital twin output with a correlation above a threshold value (e.g., top ten percent of correlations). In some embodiments, the top digital twin outputs include the three top correlated digital twin outputs. In some embodiments, more than three or less than three digital twin outputs can be included. The output circuit 54 can identify root causes using any root cause determination system to identify potential ways to fix the problems or errors identified by the digital twin 26. The output circuit 54 provides the top digital twin outputs and associated root causes to a dashboard 62, a data output 66, and a telematics system 70.

In some embodiments, the dashboard 62 is an interactive graphical user interface (GUI) that can be accessed via a mobile device, a tablet, a computer, or a work station computer. The dashboard 62 provides the top digital twin outputs and related root causes to a user. In some embodiments, the dashboard 62 is provided at a service center and aids a mechanic or technician in repairing the system 14 and/or subsystem 18. For example, the dashboard 62 may indicate a top three list of faults and the associate root causes and allow the technician to more quickly and cost effectively identify and repair a problem.

In some embodiments, the data output 66 can be used to assemble the digital twin information, the processed inputs, the top digital twin outputs and the associated root causes into data packets for use external to the vehicle 10. For example, the data output 66 may provide information to the remote digital twin 28 or another remote control system. In some embodiments, the data output 66 may be used to update the digital twin policy remote from the vehicle 10 so that the policy can be periodically updated. For example, the policy may be updated in the remote digital twin 28 based on data packets received from multiple vehicles 10 in a fleet of vehicles 10. The policy that is updated in the remote digital twin 28 can then be updated in the local digital twin 26. For example, the data output 66 can be provided during service events (or on another schedule), and the policy can then be updated on the local digital twin 26 of the vehicle 10.

In some embodiments, the telematics 70 allow the information of the controller 22 to be distributed between vehicles and remote controllers (e.g., the remote digital twin 28) in a vehicle-to-X (V2X) system. This can allow for a more integrated fleet of vehicles that gains advantages by a larger array of experiences available to the digital twin 26. The telematics 70 may communicate between vehicles 10 or with a remote controller (e.g., the remote digital twin 28).

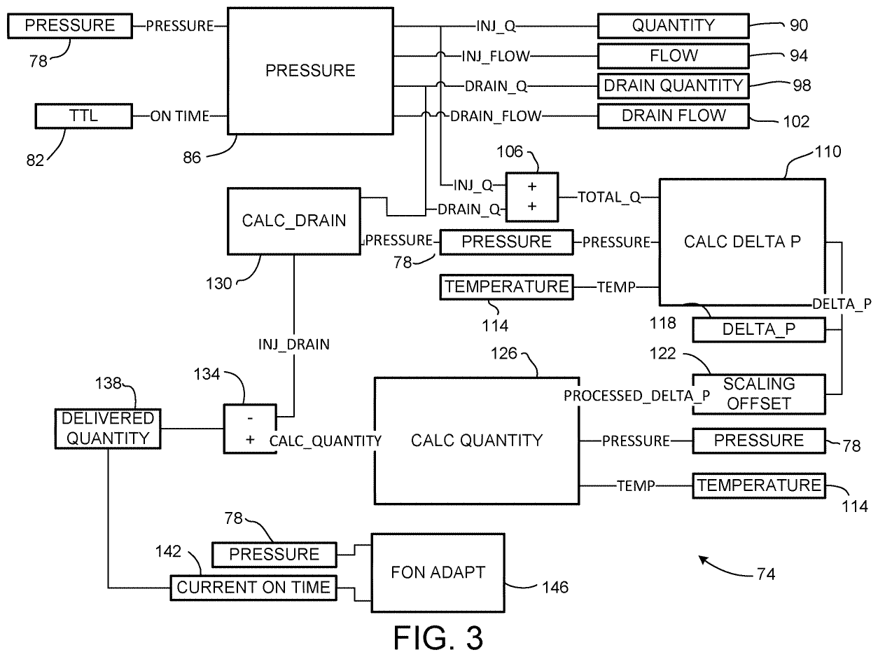

As shown in FIG. 3, a system architecture 74 can be implemented on the digital twin 26. At step 78, a fuel rail pressure is received from the input circuit 42. At step 82, an injector on-time is received from the input circuit 42. At step 86, a pressure function block receives the pressure and the injector on-time, and determines a fuel quantity delivered to the injector (INJ_Q) 90, a flow rate of fuel delivered to the injector (INJ_FLOW) 94, a quantity of fuel drained from the injector via leakage (DRAIN_Q) 98, and a flow rate of fuel draining from the injector valve (DRAIN_FLOW) 102.

At step 106, the INJ_Q 90 and the DRAIN_Q 98 are summed to provide a total quantity of fuel that is provided to step 110 including a change in pressure determination functional block (CALC DELTA P). Step 110 also receives the pressure information 78 and a fuel temperature information 114 from the input circuit 42. The step 110 determines a change in pressure (DELTA_P) 118 resulting from injector operation for the on-time 82. The DELTA_P 118 is indicative of the operation of the injector valve.

At step 122, a scaling offset is introduced including the prompt. The digital twin 26 injects the prompt (e.g., an error) into the system architecture 74. For example, the digital twin 26 may inject errors relating to an increased drain flow restriction, a reduced drain flow restriction, or a bias on a rail pressure sensor (both positive and negative). Other errors/prompts are considered and different system 14 or subsystem 18 can include different error/prompts associated with those systems. The prompts can include typical offset errors that are associated with the target errors. A list of prompts can be developed by the artificial intelligence engine of the digital twin 26, received from the telematics 70, the remote digital twin 28, and/or be reviewed form a different source (e.g., a predetermined list based on maintenance history or warrantee claims). The step 122 determines a processed change in pressure (PROCESSED_DELTA_P) based on the prompt. The PROCESSED_DELTA_P represents the change in pressure that would be expected by the fuel injector if the introduced prompt/error was present.

At step 126, the PROCESSED_DELTA_P is received by a quantity calculation functional block along with the pressure information 78 and the temperature information 114. The step 126 determines a total quantity of fuel (CALC_QUANTITY) expected to be delivered based on the prompt. In other words, the CALC_QUANTITY is the amount of fuel that would have been delivered if the prompt/error was present in the injector.

At step 130, a drain quantity of fuel (INJ_DRAIN) is determined based on the DRAIN_Q 98 and the pressure information 78. The CALC_QUANTITY from step 126 and the DRAIN_Q 98 are provided to step 134 where a difference is taken, and an expected delivered quantity of fuel is determined at step 138. The expected delivered quantity of fuel represents the actual volume of fuel that would be expected to be delivered by the injector when the prompt is present.

At step 142, the digital twin 26 determines a current on-time (e.g., the same as injector on-time of step 82) of the injector to provide the expected delivered quantity of fuel. At step 146, the current on-time and the pressure information 78 are used to determine an adapted fueling on-time: quantity curve that is based on the prompt.

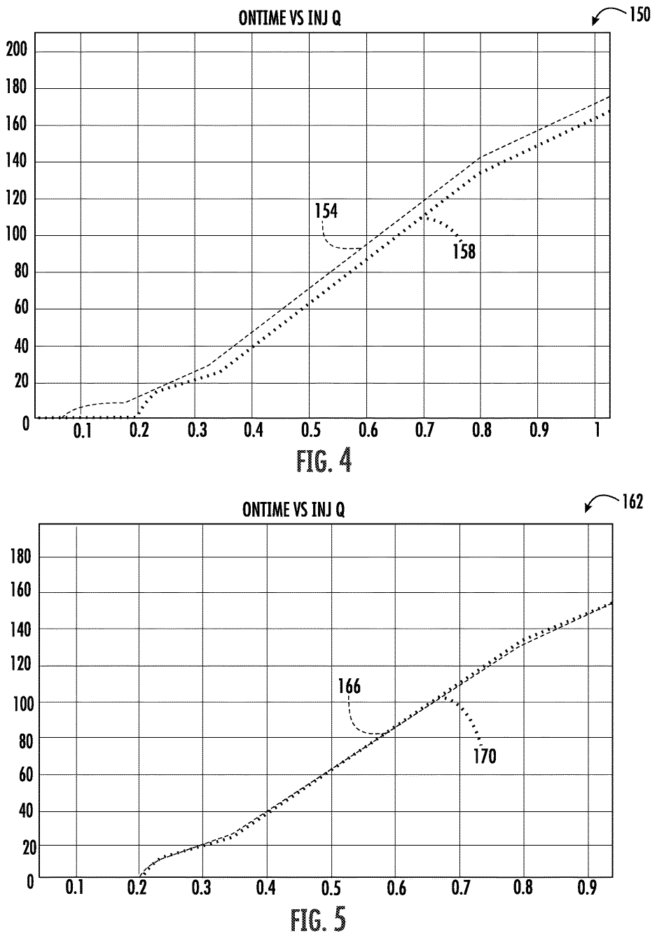

As shown in FIG. 4, the digital twin 26 produces an output including an on-time: quantity graph 150 including on-time in milliseconds on the x-axis, and milligrams of delivered fuel (e.g., the expected delivered quantity of fuel that is determined at step 138) on the y-axis. The graph 150 is provided for a specific pressure (e.g., the pressure information 78) and shows the volume of fuel provided by the injector for a given amount of on-time. A default or real world curve 154 (e.g., an ideal injector curve 154, in case no abnormality is present) represents an on-time: quantity curve that is experienced the injector in the real world. An adapted curve 158 represents an on-time: quantity curve (e.g., the adapted fueling on-time: quantity curve produced in step 146) that is produced by the digital twin 26 based on the prompt. For example, the prompt represented in graph 150 is a drain path obstruction. The correlation of the adapted curve 158 to the default curve 154 is relatively low, and the drain path obstruction prompt is assigned a low priority.

As shown in FIG. 5, the digital twin 26 produces an on-time: quantity graph 162 examining a very low drain path obstruction prompt and including a default curve 166 and an adapted curve 170. The adapted curve 170 has a very high correlation to the default curve 166 and a high priority is assigned to the very low drain path obstruction prompt by the priority circuit 50. This indicates to the output circuit 54 that the very low drain path obstruction prompt should be recommended as the error over the drain path obstruction prompt examined in FIG. 4. The output circuit 54 will determine root causes for the very low drain path obstruction prompt and provide the root causes and potential fixes to the dashboard 62.

As shown in FIG. 6, the digital twin 26 produces an on-time: quantity graph 174 examining a scaling error in a rail pressure sensor prompt and including a default curve 178 and an adapted curve 182. The correlation of the curves shows that as fueling on-time increases, the difference between the adapted curve 182 and the default curve 178 increases because the injector is experiencing scaling error.

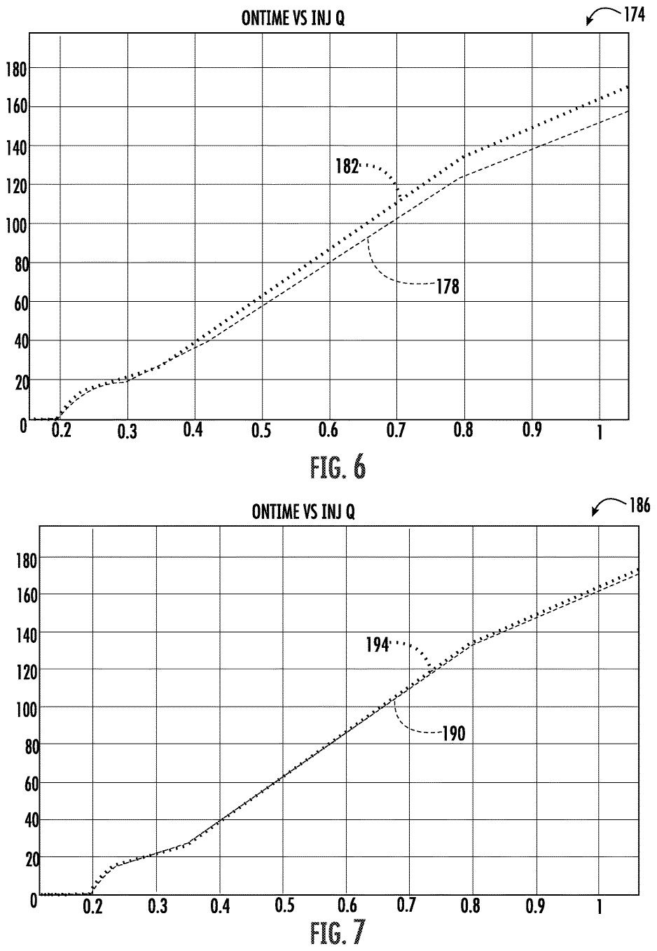

As shown in FIG. 7, the digital twin 26 produces an on-time: quantity graph 186 examining a very low scaling error in a rail pressure sensor prompt and including a default curve 190 and an adapted curve 194. The correlation of the curves shows that the adapted curve 194 and the default curve 190 stay close to each other with a high correlation because the error introduced is very low which reflects an ideal scenario for healthy sensor information and injector operation.

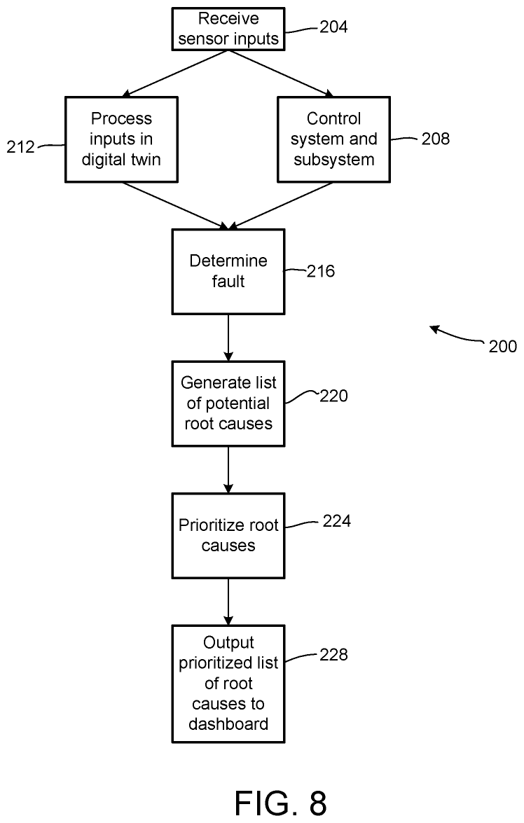

As shown in FIG. 8, the controller 22 is structured to implement a method 200 of determining faults using the digital twin 26. At step 204 the digital twin 26 receives information from the input circuit 42. At step 208, the controller 22 controls operation of the system 14 and the subsystem 18 (e.g., the injector) based on the information received at step 204. At step 212, the digital twin 26 processes the information received at step 204 and generates outputs based on prompts.

At step 216, prompts above a threshold correlation are identified as being included in a top result list (e.g., a top five list, a top ten list, a top three list, etc.) and are determined as potential faults. At step 220, root causes are correlated with the identified faults using a root cause engine, historical data etc. At step 224, the root causes and associated faults are prioritized by the priority circuit 50 based on their correlation and the output circuit 54 provides the prioritized list to the dashboard 62 at step 228.

The DELTA_Q determined by the digital twin 26 determined at step 134 includes an averaged/weighted value and an intermittent issue won't affect the average value of DELTA_Q so that the digital twin 26 output captures only the gradual drift in injector fueling. In a service event, the digital twin 26 outputs include multiple representations of all error sources that are compared against the current adapted fueling on-time and thereby indicate the most probable cause of failure at a system level.

The digital twin 26 allows for shorter service times and reliable detection of root causes associated with robust fixes. The digital twin can be achieved on-board the vehicle 10 for continuous predictions/health checks, or remote/off-board via the telematics 70 and data acquisition processes allowing offline data processing by the remote digital twin 28 to feed inputs to a service team. The digital twin 26 allows for analysis of combination failure modes like a partially blocked drain flow valve and a noisy sensor's impact on fuelling on-time.

The digital twin 26 can also be used to streamline engine tuning processes. For example, the digital twin 26 can help avoid the regular laborious method of trying to troubleshoot closed loop fueling control (CLFC) issues as the measurement events are not stored to re-create the problem. The digital twin 26 can avoid having to validate every step in CLFC tuning again.

Additionally, the digital twin 26 can learn how the system 14 (e.g., the engine) affects the subsystem 18 to find more in-depth fault possibilities. For example, the injector discussed above may be affected by the operation of non-fueling system components. The digital twin 26 is able to learn new connections and cause-effect relationships and can improve diagnostic capabilities by learning new relationships within the system 14.

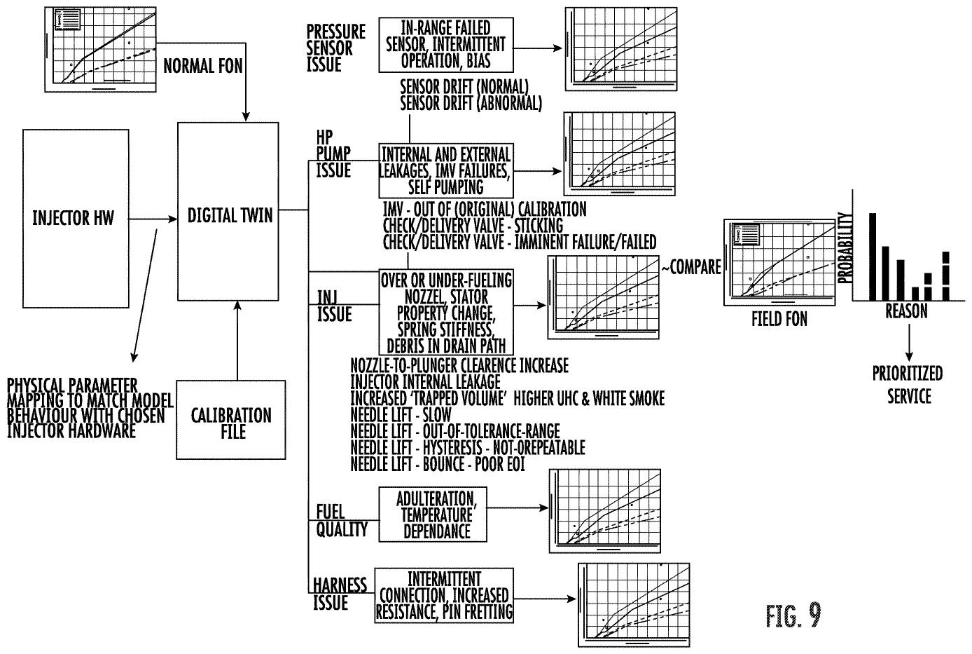

FIG. 9 shows an exemplary workflow of the method 200. The parameters of the injector (e.g., the subsystem 18) are mapped to the digital twin 26. The illustrated method 200 produces five prompts (e.g., pressure sensor issue, high pressure pump issue, injector issue, fuel quality, and harness issue) and outputs on-time: quantity curves for each. The curves are then compared to the Normal fuel on-time: quantity curves and the real world or field fueling on-time: quantity curves and a priority list is generated for use by a service team.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the disclosure as recited in the appended claims.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The term “coupled” and variations thereof, as used herein, means the joining of two members directly or indirectly to one another. Such joining may be stationary (e.g., permanent or fixed) or moveable (e.g., removable or releasable). Such joining may be achieved with the two members coupled directly to each other, with the two members coupled to each other using one or more separate intervening members, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic. For example, circuit A communicably “coupled” to circuit B may signify that the circuit A communicates directly with circuit B (i.e., no intermediary) or communicates indirectly with circuit B (e.g., through one or more intermediaries).

References herein to the positions of elements (e.g., “top,” “bottom,” “above,” “below”) are merely used to describe the orientation of various elements in the FIGURES. It should be noted that the orientation of various elements may differ according to other exemplary embodiments, and that such variations are intended to be encompassed by the present disclosure.

While various circuits with particular functionality are shown in FIG. 2, it should be understood that the controller 22 may include any number of circuits for completing the functions described herein. For example, the activities and functionalities of the control system 38 may be combined in multiple circuits or as a single circuit. Additional circuits with additional functionality may also be included. Further, the controller 22 may further control other activity beyond the scope of the present disclosure.

As mentioned above and in one configuration, the “circuits” may be implemented in machine-readable medium for execution by various types of processors, such as the processor 30 of FIG. 2. An identified circuit of executable code may, for instance, comprise one or more physical or logical blocks of computer instructions, which may, for instance, be organized as an object, procedure, or function. Nevertheless, the executables of an identified circuit need not be physically located together but may comprise disparate instructions stored in different locations which, when joined logically together, comprise the circuit and achieve the stated purpose for the circuit. Indeed, a circuit of computer readable program code may be a single instruction, or many instructions, and may even be distributed over several different code segments, among different programs, and across several memory devices. Similarly, operational data may be identified and illustrated herein within circuits and may be embodied in any suitable form and organized within any suitable type of data structure. The operational data may be collected as a single data set, or may be distributed over different locations including over different storage devices, and may exist, at least partially, merely as electronic signals on a system or network.

While the term “processor” is briefly defined above, the term “processor” and “processing circuit” are meant to be broadly interpreted. In this regard and as mentioned above, the “processor” may be implemented as one or more general-purpose processors, application specific integrated circuits (ASICs), field programmable gate arrays (FPGAs), digital signal processors (DSPs), or other suitable electronic data processing components structured to execute instructions provided by memory. The one or more processors may take the form of a single core processor, multi-core processor (e.g., a dual core processor, triple core processor, quad core processor, etc.), microprocessor, etc. In some embodiments, the one or more processors may be external to the apparatus, for example the one or more processors may be a remote processor (e.g., a cloud based processor). Alternatively or additionally, the one or more processors may be internal and/or local to the apparatus. In this regard, a given circuit or components thereof may be disposed locally (e.g., as part of a local server, a local computing system, etc.) or remotely (e.g., as part of a remote server such as a cloud based server). To that end, a “circuit” as described herein may include components that are distributed across one or more locations.

Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a computer, such as a special purpose computer or special purpose processing machine(s), to perform a certain function or group of functions.

Although the figures and description may illustrate a specific order of method steps, the order of such steps may differ from what is depicted and described, unless specified differently above. Also, two or more steps may be performed concurrently or with partial concurrence, unless specified differently above. Such variation may depend, for example, on the software and hardware systems chosen and on designer choice. All such variations are within the scope of the disclosure. Likewise, software implementations of the described methods could be accomplished with standard programming techniques with rule-based logic and other logic to accomplish the various connection steps, processing steps, comparison steps, and decision steps.

It is important to note that the construction and arrangement of the digital twin 26 as shown in the various exemplary embodiments is illustrative only. Additionally, any element disclosed in one embodiment may be incorporated or utilized with any other embodiment disclosed herein. Although only one example of an element from one embodiment that can be incorporated or utilized in another embodiment has been described above, it should be appreciated that other elements of the various embodiments may be incorporated or utilized with any of the other embodiments disclosed herein.

What is claimed is:

1. An apparatus, comprising:
one or more processing circuits comprising one or more memory devices coupled to one or more processors, the one or more memory devices configured to store instructions thereon that, when executed by the one or more processors, cause the one or more processors to:
receive information from at least one sensor;
control operation of a vehicle subsystem based on the information;
generate a digital twin output based on the information;
generate a prioritized list of faults based on the digital twin output; and
provide the prioritized list to a dashboard.

2. The apparatus of claim 1, wherein the one or more processing circuits are located on-board a vehicle.

3. The apparatus of claim 2, wherein the one or more processing circuits reside within an engine control module.

4. The apparatus of claim 1, wherein the digital twin output includes a fueling on-time-to-quantity indicator regarding a fuel injector.

5. The apparatus of claim 4, wherein the one or more memory devices are further configured to store instructions thereon that, when executed by the one or more processors, cause the one or more processors to:
compare the digital twin output to an actual output; and
generate the prioritized list of faults based on a correlation of the digital twin output to the actual output.

6. The apparatus of claim 1, wherein the one or more memory devices are further configured to store instructions thereon that, when executed by the one or more processors, cause the one or more processors to determine a plurality of faults from at least one prompt above a threshold correlation.

7. The apparatus of claim 1, wherein the one or more memory devices are further configured to store instructions thereon that, when executed by the one or more processors, cause the one or more processors to communicate with a second digital twin on a remote control system.

8. A system, comprising:
a vehicle system; and
a controller coupled to the vehicle system, the controller having one or more processors coupled with at least one memory, the controller configured to:
receive information from at least one sensor;
control operation of the vehicle system based on the information;
generate a digital twin output based on the information;
generate a prioritized list of faults based on the digital twin output; and
provide the prioritized list to a user interface on a computing device.

9. The system of claim 8, wherein the controller is further configured to:
compare the digital twin output to an output of the vehicle system to determine a correlation; and
generate the prioritized list of faults based on the correlation of the digital twin output to the actual output.

10. The system of claim 8, wherein the controller is further configured to determine a plurality of faults based on prompts above a threshold correlation.

11. The system of claim 8, wherein the controller is further configured to communicate with a second digital twin on a remote control system to send telematics data.

12. The system of claim 8, wherein the controller is further configured to determine, using an artificial intelligence model of the digital twin, the digital twin output from the information.

13. The system of claim 8, wherein the digital twin output includes a fueling on-time-to-quantity indicator regarding a fuel injector.

14. The system of claim 8, wherein the controller resides on a vehicle, and wherein the vehicle system comprises at least one of an aftertreatment system, a transmission, or an engine.

15. A method of generating a prioritized list of faults using a digital twin, the method comprising:
receiving, by one or more processors, information from at least one sensor;
controlling, by the one or more processors, operation of a vehicle system based on the information;
generating, by the one or more processors, a digital twin output based on the information;
generating, by the one or more processors, a prioritized list of faults based on the digital twin output; and
providing, by the one or more processors, the prioritized list to an interface on a computing device.

16. The method of claim 15, further comprising:
comparing, by the one or more processors, the digital twin output to an output of the vehicle system to determine a correlation; and
generating, by the one or more processors, the prioritized list of faults based on the correlation of the digital twin output to the output.

17. The method of claim 15, further comprising determining, by the one or more processors, a plurality of faults based on prompts above a threshold correlation.

18. The method of claim 15, further comprising communicating, by the one or more processors, with a second digital twin on a remote control system.

19. The method of claim 15, further comprising determining, by the one or more processors and using an artificial intelligence model of the digital twin, the digital twin output from the information.

20. The method of claim 15, wherein the one or more processors are at least part of a controller residing on a vehicle.
